(19) United States
(12) Patent Application Publication
(10) Pub. No.: US 2025/0167056 A1
(43) Pub. Date: May 22, 2025

(54) SEMICONDUCTOR PACKAGE

(71) Applicant: Samsung Electronics Co., Ltd., Suwon-si (KR)

(72) Inventors: Gyuhyeong KIM, Suwon-si (KR); Chaein MOON, Suwon-si (KR)

(73) Assignee: Samsung Electronics Co., Ltd., Suwon-si (KR)

(21) Appl. No.: 18/744,964

(22) Filed: Jun. 17, 2024

(30) Foreign Application Priority Data
Nov. 17, 2023 (KR) 10-2023-0159711

(51) Int. Cl. H01L 23/13; H01L 23/00; H01L 23/36; H01L 23/498

(52) U.S. Cl. CPC H01L 23/13; H01L 23/36; H01L 24/13; H01L 24/80; H01L 23/49816; H01L 2224/13023; H01L 2224/13082; H01L 2224/16111; H01L 2224/81024

(57) ABSTRACT

Provided is a semiconductor package including a substrate defining a first recess portion and a plurality of second recess portions, the plurality of second recess portions are arranged on a bottom surface of the first recess portion, a semiconductor chip in the first recess portion of the substrate, solder balls arranged in the plurality of second recess portions of the substrate and electrically connected to the semiconductor chip, and a heat dissipation structure on the substrate and the semiconductor chip, the bottom surface of the first recess portion of the substrate being on a higher level than upper surfaces of the solder balls.

### CROSS-REFERENCE TO RELATED APPLICATION

This application is based on and claims priority under 35 U. S. C. § 119 to Korean Patent Application No. 10-2023-0159711, filed on Nov. 17, 2023 in the Korean Intellectual Property Office, the disclosure of which is incorporated by reference herein in its entirety.

### BACKGROUND

The present inventions relate to semiconductor packages, and particularly, to a substrate, bumps, and a semiconductor chip of the semiconductor packages.

The semiconductor package is an integrated circuit chip suitable for electronic products. In general, the semiconductor package may include a semiconductor chip mounted on a printed circuit board. The semiconductor chip may be electrically connected to the printed circuit board using bonding wires or bumps. With the development of electronics industry, the manufacturing process of the semiconductor package has become complicated.

### SUMMARY

The inventive concepts provide semiconductor packages manufactured through a simplified method.

The inventive concepts provide semiconductor packages having improved thermal characteristics and reliability.

According to some aspects of the inventive concepts, there is provided a semiconductor package including a substrate defining a first recess portion and a plurality of second recess portions, the plurality of second recess portions on a bottom surface of the first recess portion, a semiconductor chip in the first recess portion of the substrate, solder balls in the plurality of second recess portions of the substrate and electrically connected to the semiconductor chip, and a heat dissipation structure on the substrate and the semiconductor chip, the bottom surface of the first recess portion of the substrate being on a higher level than upper surfaces of the solder balls.

According to some aspects of the inventive concepts, there is provided a semiconductor package including a substrate including a first upper surface, a second upper surface on a lower level than the first upper surface, and a third upper surface on a lower level than the second upper surface, bumps on the third upper surface of the substrate, and a semiconductor chip on the second upper surface of the substrate and on the bumps and connected to the bumps, each of the bumps including a conductive pillar and a solder ball on a lower surface of the conductive pillar, at least a portion of the second upper surface of the substrate being between the bumps and on a higher level than the upper surface of the solder ball.

According to some aspects of the inventive concepts, there is provided a semiconductor package including a substrate defining a first recess portion and a plurality of second recess portions, the first recess portion is defined by a first upper surface of the substrate and the plurality of second recess portions are defined by and extend from a bottom surface of the first recess portion, solder ball terminals on a lower surface of the substrate, a semiconductor chip in the first recess portion of the substrate, bumps in the plurality of second recess portions of the substrate and connected to the semiconductor chip, a heat dissipation plate on the substrate and on the semiconductor chip, and a thermally conductive layer between the semiconductor chip and the heat dissipation plate and between the substrate and the heat dissipation plate so as to cover an upper surface of the semiconductor chip, the bottom surface of the first recess portion of the substrate being on a lower level than the first upper surface of the substrate, and bottom surfaces of the plurality of second recess portions of the substrate being on a lower level than the bottom surface of the first recess portion of the substrate, the substrate including first substrate pads exposed through the plurality of second recess portions and connected to the bumps, substrate wirings in the substrate and connected to the first substrate pads, and second substrate pads on the lower surface of the substrate and between the substrate wirings and the solder ball terminals, each of the bumps including a conductive pillar and a solder ball on a lower surface of the conductive pillar, and the bottom surface of the first recess portion of the substrate being on a higher level than the lower surface of the conductive pillar.

### BRIEF DESCRIPTION OF THE DRAWINGS

Embodiments will be more clearly understood from the following detailed description taken in conjunction with the accompanying drawings in which:

FIG. 1A is a plan view of a semiconductor package according to some example embodiments;

FIG. 1B is a plan view of a substrate according to some example embodiments;

FIG. 1C is a cross-sectional view of the semiconductor package of FIG. 1A taken along line I-I′;

FIG. 1D is an enlarged view of region II of the semiconductor package of FIG. 1C;

FIG. 1E is a diagram for explaining bumps and a substrate according to some example embodiments;

FIG. 1F is a diagram for explaining an arrangement relation between bumps, a semiconductor chip, and a substrate;

FIG. 1G is a diagram for explaining an arrangement relation between bumps, a semiconductor chip, and a substrate;

FIG. 2A is a plan view of a semiconductor package according to some example embodiments;

FIG. 2B is a plan view of a semiconductor package according to some example embodiments;

FIG. 3A is a plan view of a semiconductor package according to some example embodiments;

FIG. 3B is a plan view of a semiconductor package according to some example embodiments;

FIG. 4 is a plan view of a semiconductor package according to some example embodiments; and

FIGS. 5A to 5G are diagrams for explaining a method of manufacturing a semiconductor package.

### DETAILED DESCRIPTION OF THE EMBODIMENTS

Throughout the present specification, the same reference numerals are used for the same components. A semiconductor package and a method of manufacturing the semiconductor package according to the inventive concept will be described.

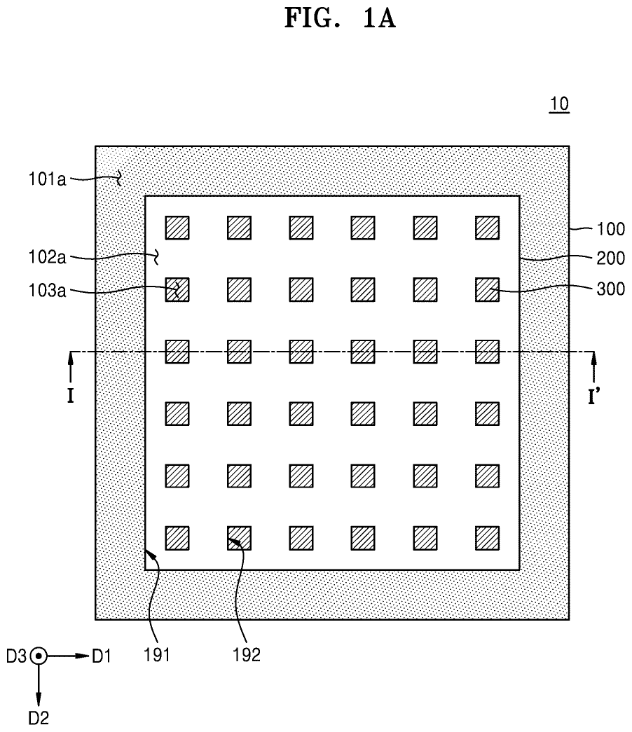

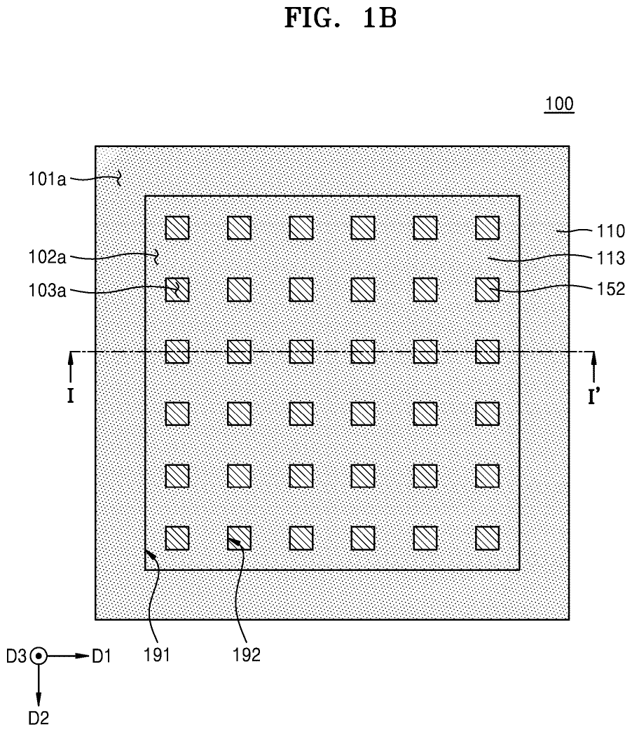

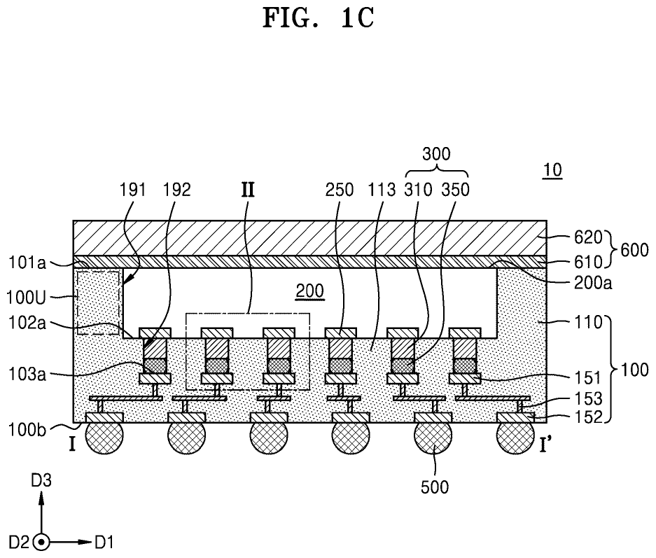

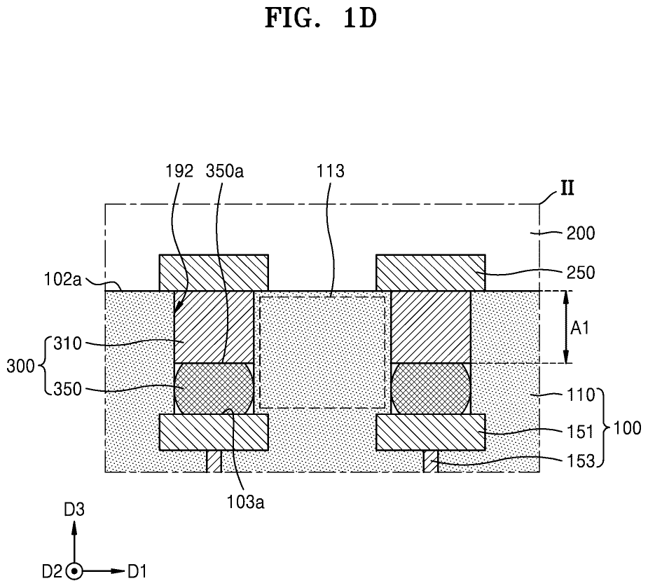

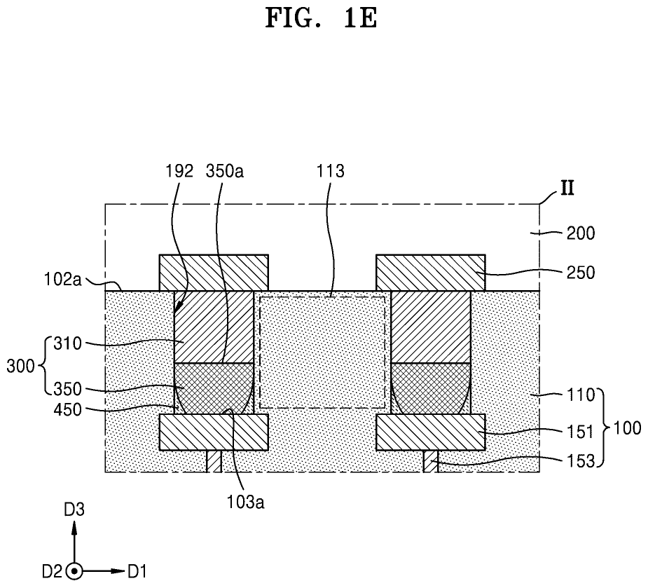

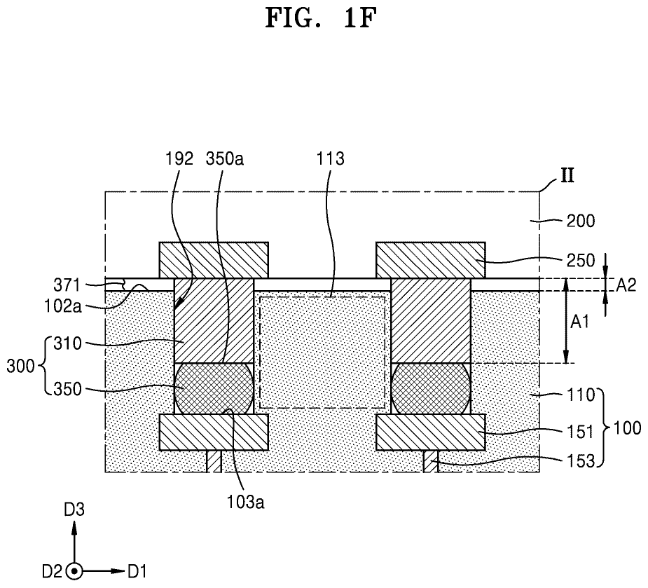

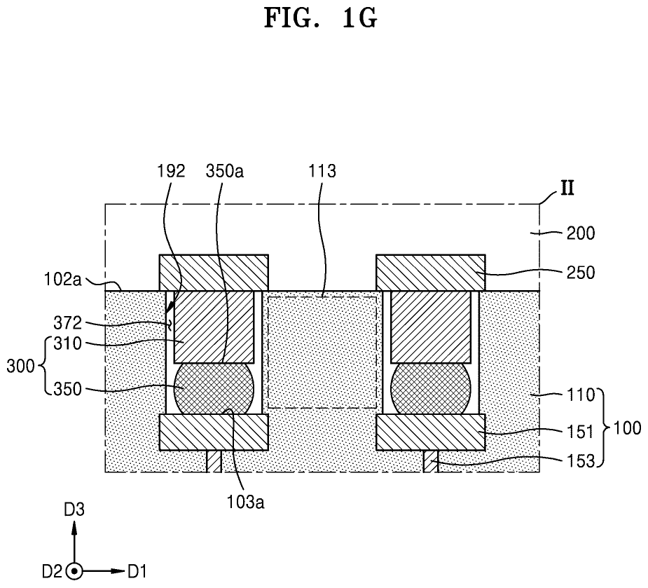

FIG. 1A is a plan view of a semiconductor package according to some example embodiments. FIG. 1B is a plan view of a substrate according to some example embodiments. FIG. 1C is a cross-sectional view of the semiconductor package of FIG. 1A taken along line I-I′. FIG. 1D is an enlarged view of region II of the semiconductor package of FIG. 1C.

Referring to FIGS. 1A to 1D, the semiconductor package 10 may include a substrate 100, solder ball terminals 500, a semiconductor chip 200, bumps 300, and a heat dissipation structure 600. The substrate 100 may, for example, include a printed circuit board (PCB). The substrate 100 may include a center region and an edge region in a planar view. The center region of the substrate 100 may be surrounded by the edge region. The edge region of the substrate 100 may be provided between the center region and side walls of the substrate 100.

As in FIGS. 1B and 1C, the substrate 100 may have a lower surface 100b and a first upper surface 101a. The first surface 101a of the substrate 100 may face the lower surface 100b of the substrate 100. A first direction D1 may be parallel to the first upper surface 101a of the substrate 100. A second direction D2 may be parallel to the first surface 101a of the substrate 100 and may cross the first direction D1. A third direction D3 may be perpendicular or substantially perpendicular to the first upper surface 101a of the substrate 100. The third direction D3 may be a vertical direction.

The substrate 100 may include a first recess portion 191 and second recess portions 192. The first recess portion 191 may be provided in the substrate 100 and on the first upper surface 101a of the substrate 100. The first recess portion 191 may be recessed from the first upper surface 101a of the substrate 100 to the inside of the substrate 100. For example, a portion of the substrate 100 may be removed to form the first recess portion 191. The first recess portion 191 may be provided in the center region of the substrate 100 in a planar view. A bottom surface of the first recess portion 191 may be provided in the substrate 100 and apart from the lower surface 100b of the substrate 100. Since the first recess portion 191 is formed, the substrate 100 may include a second upper surface 102a. The second upper surface 102a of the substrate 100 may correspond to the bottom surface of the first recess portion 191. The second upper surface 102a of the substrate 100 may be provided on a lower level than the first upper surface 101a. The level of a component may refer to the vertical level. The first recess portion 191 may be defined by the inner sidewalls of the substrate 100 and second upper surface 102a.

The second recess portions 192 may be provided on the bottom surface of the first recess portion 191. For example, the second recess portions 192 may be provided in the substrate 100 and on the second upper surface 102 of the substrate 100. For example, the second recess portions 192 may be portions depressed from the second upper surface 102a of the substrate 100 toward the lower surface 100b of the substrate 100. Bottom surfaces of the second recess portions 192 may be provided in the substrate 100 and apart from the lower surface 100b of the substrate 100. Since the second recess portions 192 are formed, the substrate 100 may include a third upper surface 103a and partition walls 113. The third upper surface 103a of the substrate 100 may correspond to the bottom surfaces of the second recess portions 192. The third upper surface 103a of the substrate 100 may be provided on a lower level than the second upper surface 102a. The second recess portions 192 may be apart from each other sideways. For example, the second recess portions 192 may be apart from each other in the first direction D1 or the second direction D2. The partition walls 113 may be respectively provided between the second recess portions 192. Components being apart from each other sideways may refer to components being apart from each other horizontally. Being “horizontal” may refer to being parallel to the first upper surface 100a of the substrate 100. The second recess portions 192 may be defined by the lower inner sidewalls of the substrate 100 and the third upper surfaces 103a.

The substrate 100 may include an insulating layer 110, first substrate pads 151, second substrate pads 152, and substrate wirings 153. For example, the insulating layer 110 may include an insulating material, and/or at least one of an organic material such as insulating resin and an inorganic material such as glass fibers. For example, the insulating layer 110 may include a prepreg made from pre-impregnated glass fibers in an inorganic material. Although not shown, the insulating layer 110 may be multi-layered.

The first substrate pads 151 may be provided on the second upper surface 102a of the substrate 100. The second recess portions 192 may expose the upper surface of the first substrate pads 151. For example, the bottom surfaces of the second recess portions 192 may correspond to the upper surfaces of the first substrate pads 151. The second substrate pads 152 may be provided on the lower surface 100b of the substrate 100. The substrate wirings 153 may be provided in the substrate 100. For example, the substrate wirings 153 may be provided in the insulating layer 110 and be respectively electrically connected to the second substrate pads 152. The second substrate pads 152 may be electrically connected to the first substrate pads 151 through the substrate wirings 153, respectively. The first substrate pads 151, the second substrate pads 152, and the substrate wirings 153 may each include metal materials such as copper, aluminum, tungsten, titanium, and/or an alloy thereof. Being electrically connected to the substrate 100 may refer to being electrically connected to at least one of the first substrate pads 151, the second substrate pads 152, and the substrate wirings 153. Being electrically connected to a component may refer to being directly connected to a component or being indirectly connected to a component through another conductive component.

The solder ball terminals 500 may be provided on the lower surface 100b of the substrate 100. For example, the solder ball terminals 500 may be respectively provided on the lower surfaces of the second substrate pads 152 to be respectively connected to the second substrate pads 152. Accordingly, the solder ball terminals 500 may be electrically connected to the first substrate pads 151, respectively through each of the second substrate pads 152 and the substrate wirings 153. The solder ball terminals 500 may include a solder material. The solder material may include, for example, tin (Sn), silver (Ag), zinc (Zn), and/or an alloy thereof.

The semiconductor chip 200 may be provided in the first recess portion 191. The semiconductor chip 200 may be provided on the second upper surface 102a of the substrate 100. The semiconductor chip 200 may be a non-memory chip or a memory chip. The memory chip may include electronic data processing (EDP) circuits, but is not limited thereto. The semiconductor chip 200 may include chip pads 250 and integrated circuits (not shown). The integrated circuits may be provided in the semiconductor chip 200 and be adjacent to a lower surface of the semiconductor chip 200. The chip pads 250 may be arranged on the lower surface of the semiconductor chip 200. The chip pads 250 may include a metal such as aluminum, copper, gold, and/or nickel. The chip pads 250 may be electrically connected to the integrated circuits. Being electrically connected to the semiconductor chip 200 may refer to being electrically connected to the integrated circuits through the chip pads 250 of the semiconductor chip 200.

An upper portion 100U of the substrate 100 may be provided on the side walls of the semiconductor chip 200. For example, the upper portion 100U of the substrate 100 may surround the side walls of the semiconductor chip 200. Accordingly, since a process of forming a molding layer covering the side walls of the semiconductor chip 200 may be omitted, and the manufacturing of the semiconductor package 10 may be simplified and improved. The upper portion 100U of the substrate 100 may include an upper portion of the insulating layer 110. In some example embodiments, since the semiconductor chip 200 is provided in the first recess portion 191, the side walls of the semiconductor chip 200 may face first inner walls of the substrate 100. The first inner walls of the substrate 100 may correspond to the side walls of the first recess portion 191. For example, the side walls of the semiconductor chip 200 may be physically in contact with the first inner walls of the substrate 100.

A level difference between an upper surface 200a of the semiconductor chip 200 and the first upper surface 101a of the substrate 100 may be about or exactly 50 μm or less, for example, about or exactly 50 μm to about or exactly 0 μm, about or exactly 50 μm to about or exactly 0.1 μm, about or exactly 50 μm to about or exactly 20 μm, or about or exactly 40 μm to about or exactly 10 μm. For example, the upper surface 200a of the semiconductor chip 200 may be provided on a level the same or substantially the same as the first upper surface 101a of the substrate 100.

The bumps 300 may be provided in the second recess portions 192, respectively. The bumps 300 may be provided on the third upper surface 103a of the substrate 100. For example, each of the bumps 300 may be provided between the third upper surface 103a and the semiconductor chip 200 of the substrate 100 to be connected to both the first substrate pads 151 and the chip pads 250.

Each bump 300 may include a conductive pillar 310 and a solder ball 350. The conductive pillar 310 may be provided on a lower surface of the chip pad 250 corresponding to the conductive pillar 310 and may be connected to the chip pad 250. The conductive pillar 310 may include, for example, a metal such as copper. The solder ball 350 may be provided on a lower surface of the conductive pillar 310. The lower surface of the conductive pillar 310 may be provided on the same level as an upper surface 350a of the solder ball 350. The solder ball 350 may be bonded with, among the first substrate pads 151, the upper surface of the first substrate pad 151 corresponding to the solder ball 350 and be electrically connected to the first substrate pad 151. Accordingly, the semiconductor chip 200 may be electrically connected to the substrate 100 through the bumps 300. The solder ball 350 may include a different material from those of the conductive pillar 310 and the first substrate pad 151. For example, the solder ball 350 may include a metal such as a solder material.

Since the bumps 300 are respectively provided in the second recess portions 192, the partition walls 113 may be provided between the bumps 300. Accordingly, the bumps 300 may be apart from each other sideways. For example, through the partition walls 113, electrical shorts between the bumps 300 may be prevented or reduced.

The second upper surface 102a of the substrate 100 may include the upper surfaces of the partition walls 191. According to some example embodiments, at least a portion of the second upper surface 102a of the substrate 100 may be provided between the bumps 300 in a planar view. The second upper surface 102a of the substrate 100 may be provided on a higher level than the upper surface 350a of the solder ball 350. Accordingly, the solder ball 350 may be prevented or reduced from being in contact with other bumps 300 adjacent thereto in a reflow process of the solder ball 350. The occurrence of electrical shorts between the bumps 300 may be further prevented or reduced. A space between the lower surface of the semiconductor chip 200 and the second upper surface 102a of the substrate 100 may be about or exactly 50% or less (for example, about or exactly 0% or 0.1%) than a height A1 of the conductive pillar 310. Accordingly, the occurrence of electrical shorts between the bumps 350 may be prevented or reduced. For example, as shown in FIG. 1D, the second upper surface 102a of the substrate 100 may be physically in contact with the semiconductor chip 200.

The substrate wirings 153 may not be exposed to the side walls of the second recess portions 192. The bumps 300 may be apart from the substrate wirings 153. The bumps 300 may be respectively connected to the substrate wirings 153 through the first substrate pads 151, respectively.

In some example embodiments, since the bumps 300 are provided in the second recess portions 192, respectively, forming an underfill layer between the lower surface of the semiconductor chip 200 and the substrate 100 may be omitted. Accordingly, the manufacturing process of the semiconductor package 10 may be further simplified and improved. In addition, the occurrence of an electrical shorts between the bumps 300 due to a void in the underfill layer may be prevented or reduced. The semiconductor package 10 may have improved reliability.

In some example embodiments, the side walls of the bumps 300 may physically in contact with the substrate 100. For example, at least one of the solder ball 350 and the conductive pillar 310 may be physically in contact with the inner walls of the second recess portions 192.

As shown in FIG. 1C, the heat dissipation structure 600 may be provided on the semiconductor chip 200 and the substrate 100. When the semiconductor package 10 operates, heat generated by the semiconductor chip 200 may be released quickly through the heat dissipation structure 600. The heat dissipation structure 600 may protect the semiconductor chip 200. Accordingly, the molding layer covering the upper surface 200a of the semiconductor chip 200 may be omitted. Accordingly, the manufacturing process of the semiconductor package 10 may be further simplified and improved.

The heat dissipation structure 600 may include at least one of a thermally conductive layer 610 and a heat dissipation plate 620. The heat dissipation plate 620 may be provided on the first upper surface 200a of the semiconductor chip 200 and the first upper surface 101a of the substrate 100. The heat dissipation plate 620 may include a material with high heat resistance. For example, the heat resistance of the heat dissipation plate 620 may be about or exactly 0.05° C./W to about or exactly 1.50° C./W. Since the heat resistance of the heat dissipation plate 620 is about or exactly 1.50° C./W or less, for example about or exactly 0° C./W or 0.05° C./W, heat generated by the semiconductor chip 200 may be dissipated more quickly to the outside through the heat dissipation plate 620. The heat dissipation plate 620 may include, for example, a metal such as aluminum, copper, and/or an alloy thereof.

The thermally conductive layer 610 may be provided between the upper surface 200a of the semiconductor chip 200 and the heat dissipation plate 620 and between the first upper surface 101a of the substrate 100 and the heat dissipation plate 620. For example, the thermally conductive layer 610 may be provided in a gap region between the semiconductor chip 200 and the heat dissipation plate 620 and between the substrate 100 and the heat dissipation plate 620 to fill in the gap region. The thermally conductive layer 610 may be in physical contact with the upper surface 200a of the semiconductor chip 200 and the first upper surface 101a of the substrate 100. The thermally conductive layer 610 may have a thermal conductivity higher than the air. Accordingly, during the operation of the semiconductor package 10, heat generated by the semiconductor chip 200 may be transferred more quickly to the heat dissipation plate 620 through the thermally conductive layer 610. The thermally conductive layer 610 may act as an adhesive layer. For example, the heat dissipation plate 620 may be attached to the semiconductor chip 200 and the substrate 100 by the thermally conductive layer 610.

The thermally conductive layer 610 may include a different material from that of the heat dissipation structure 600. For example, the thermally conductive layer 610 may include a thermal interface material (TIM). The thermal interface material may include, for example, a polymer and thermally conductive particles. The thermally conductive particles may be dispersed within a polymer. The thermally conductive particles may include metal. In other examples, the thermally conductive layer 610 may be manufactured using a solder paste material. In this case, the thermally conductive layer 610 may include conductive materials such as Sn, Pb, Ag, or an alloy thereof.

The thickness of the thermally conductive layer 610 may be about or exactly 50 μm to about or exactly 100 μm. Since the thermally conductive layer 610 has a thickness of about or exactly 100 μm or less, for example about or exactly 0 μm or 50 μm, the semiconductor package 10 may be miniaturized.

FIG. 1E is a diagram for explaining the bumps 300 and the substrate 100 according to some example embodiments and corresponds to an enlarged view of region II of FIG. 1C. Hereinafter, to simplify the description, a single first substrate pad 151 and a single second recess portion 192 are described.

Referring to FIG. 1E, the semiconductor package 10 (see FIGS. 1A and 1C) may further include a flux pattern 450. The flux pattern 450 may be provided on the lower surface or the side walls of the solder ball 350. For example, the flux pattern 450 may be provided in the second recess portion 192 and between the solder ball 350 and the substrate 100. The lower surface of the center region of the solder ball 350 may be connected to the first substrate pad 151 corresponding to the solder ball 350. The lower surface of an edge region of the solder ball 350 or a side surface of the solder ball 350 may be covered by the flux pattern 450. The flux pattern 450 may further cover a portion of the upper surface of the first substrate pad 151. The flux pattern 450 may include a flux material. The flux material may include an organic matter such as rosin or resin. A plurality of flux patterns 450 may be provided. In this case, the plurality of flux patterns 450 may respectively be provided in the plurality of second recess portions 192 and may cover at least a portion of the bumps 300.

FIG. 1F is a diagram for explaining an arrangement relation between the bumps, the semiconductor chip, and the substrate, according to some example embodiments and corresponds to an enlarged view of region II of FIG. 1C. Hereinafter, redundant descriptions are omitted.

Referring to FIG. 1F, a first gap region 371 may be provided between the lower surface of the semiconductor chip 200 and the second upper surface 102a of the substrate 100. For example, the semiconductor chip 200 may be apart from the second upper surface 102a of the substrate 100. The first gap region 371 may correspond to a region between the semiconductor chip 200 and the bottom surface of the first recess portion 191 (see FIG. 1D). The first gap region 371 may be an empty space in a vacuum state or an empty space occupied by air (for example, a desired gas, atmosphere, or mixture). A space A2 between the lower surface of the semiconductor chip 200 and the second upper surface 102a of the substrate 100 may be 50% or less (for example, 0% or 0.1%) than a height A1 of the conductive pillar 310. Accordingly, an electrical short between the bumps 300 may be prevented or reduced in the reflow process of the solder ball 350.

FIG. 1G is a diagram for explaining an arrangement relation between the bumps, the semiconductor chips, and the substrates, according to some example embodiments, and corresponds to an enlarged view of region II of FIG. 1C. Hereinafter, in the description of FIG. 1G, a single bump and a single second recess portion will be described.

Referring to FIG. 1G, a second gap region 372 may be provided between the bump 300 and the substrate 100. For example, at least a portion of the side wall of the bump 300 may be apart from the side walls of the second recess portion 192 to form the second gap region 372. The second gap region 372 may be provided between the bump 300 and the substrate 100. For example, the second gap region 372 may be provided between the substrate 100 and the conductive pillar 310. In other examples, the second gap region 372 may be provided between the substrate 100 and the solder ball 350. In other examples, the second gap region 372 may be provided between the substrate 100 and the conductive pillar 310 and between the substrate 100 and the solder ball 350. The second gap region 372 may be an empty space in a vacuum state or an empty space occupied by air.

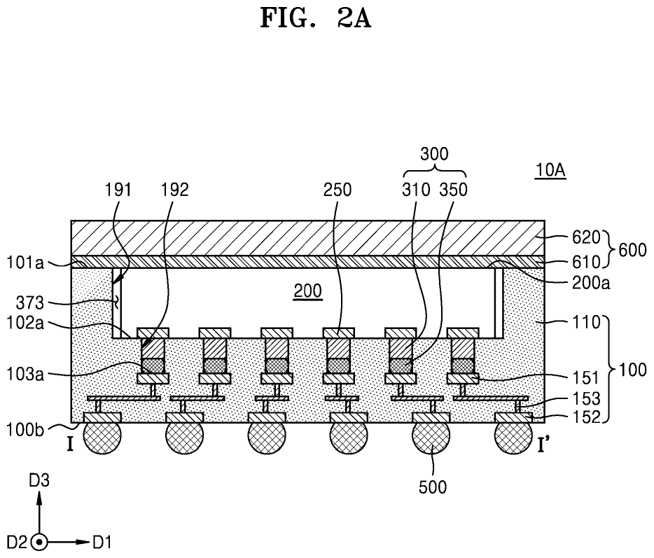

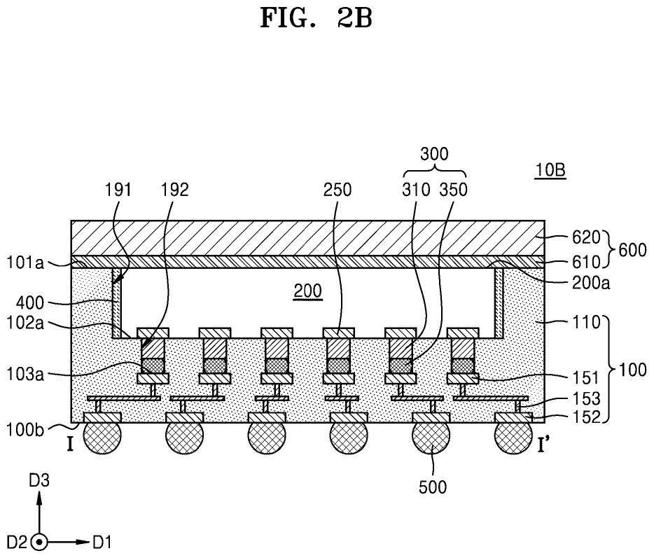

FIG. 2A is a cross-sectional view for explaining the semiconductor package according to some example embodiments, taken along line I-I′ of FIG. 1B.

Referring to FIG. 2B, a semiconductor package 10A may include the substrate 100, the solder ball terminals 500, the semiconductor chip 200, the bumps 300, and the heat dissipation structure 600. The substrate 100, the solder ball terminal 500, the semiconductor chip 200, the bumps 300, and the heat dissipation structure 600 may be the same or substantially the same as those described in the examples of FIGS. 1A to 1G. The side wall of the semiconductor chip 200 may be apart from the substrate 100 to form a third gap region 373. The third gap region 373 may be provided between the side walls of the semiconductor chip 200 and inner walls of the first recess portions 191. The third gap region 373 may be an empty space in a vacuum state or an empty space occupied by air. The heat dissipation structure 600 may block an upper portion of the third gap region 373.

FIG. 2B is a cross-sectional view for explaining the semiconductor package according to some example embodiments, taken along line I-I′ of FIG. 1B.

Referring to FIG. 2B, a semiconductor package 10B may include a gap-fill layer 400 in addition to the substrate 100, the solder ball terminals 500, the semiconductor chip 200, the bumps 300, and the heat dissipation structure 600. The substrate 100, the solder ball terminal 500, the semiconductor chip 200, the bumps 300, and the heat dissipation structure 600 may be the same or substantially the same as those described in the examples of FIGS. 1A to 1G. The side wall of the semiconductor chip 200 may be separated from the substrate 100. For example, the semiconductor chip 200 may be apart from the side walls of the first recess portion 191.

The gap-fill layer 400 may be provided in the third gap region 373 provided between the side walls of the semiconductor chip 200 and the first inner wall of the substrate 100. The gap-fill layer 400 may cover the side walls of the semiconductor chip 200 and the side walls of the first recess portion 191. The gap-fill layer 400 may include an organic material such as an epoxy-based polymer.

The heat dissipation structure 600 may be provided on the upper surface of the gap-fill layer 400, the upper surface 200a of the semiconductor chip 200, and the first upper surface 101a of the substrate 100.

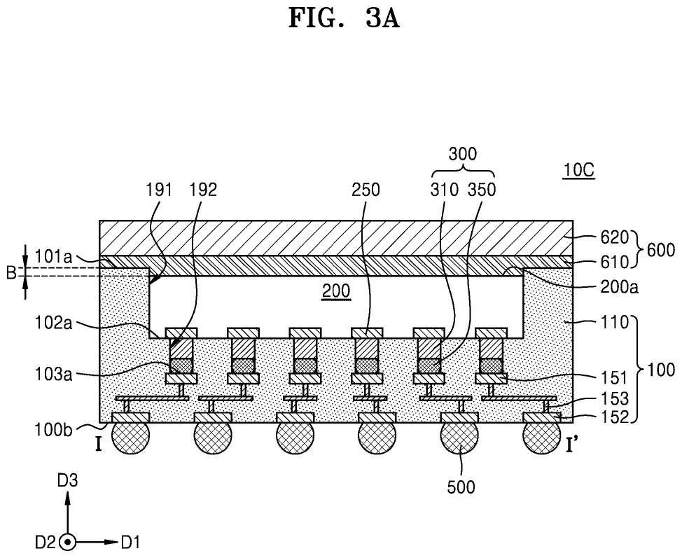

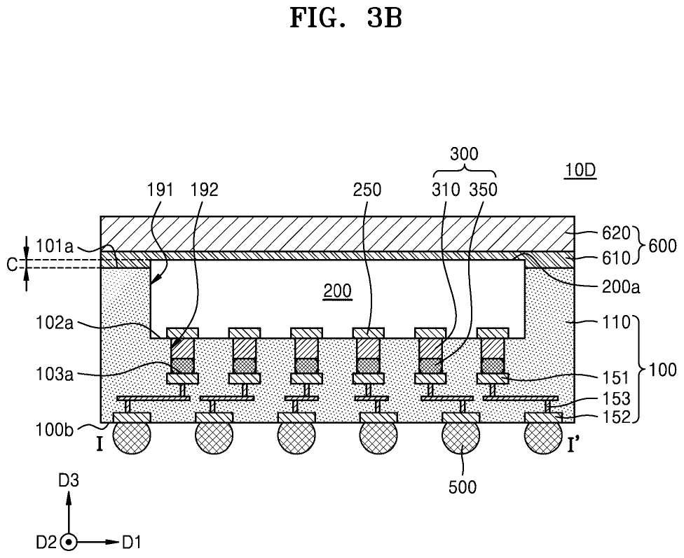

FIG. 3A is a cross-sectional view for explaining the semiconductor package according to some example embodiments, taken along line I-I′ of FIG. 1B.

Referring to FIG. 3A, a semiconductor package 10C may include the substrate 100, the solder ball terminals 500, the semiconductor chip 200, the bumps 300, and the heat dissipation structure 600.

The upper surface 200a of the semiconductor chip 200 may be provided on a lower level than that of the second upper surface 102a of the substrate 100. The level difference B between the upper surface 200a of the semiconductor chip 200 and the first upper surface 101a of the substrate 100 may be about or exactly 50 μm or less, for example, about or exactly 50 μm to about or exactly 0 μm, about or exactly 50 μm to about or exactly 0.1 μm, about or exactly 50 μm to about or exactly 20 μm, or about or exactly 40 μm to about or exactly 10 μm.

The thermally conductive layer 610 may cover the upper surface 200a of the semiconductor chip 200 and the first upper surface 101a of the substrate 100. The thermally conductive layer 610 may buffer the level difference between the upper surface 200a of the semiconductor chip 200 and the first upper surface 101a of the substrate 100. The upper surface of the thermally conductive layer 610 may be flat or substantially flat. Since the thermally conductive layer 610 has a thickness of about or exactly 50 μm or more (for example, about or exactly 50 μm to 100 μm), the level difference B between the upper surface 200a of the semiconductor chip 200 and the first upper surface 101a of the substrate 100 may be well buffered by the thermally conductive layer 610. That is, the level difference may be filled by the thermally conductive layer 610 to provide the flat or substantially flat upper surface of the thermally conductive layer 610. The heat dissipation plate 620 may be provided on the thermally conductive layer 610.

FIG. 3B is a cross-sectional view for explaining the semiconductor package according to some example embodiments, taken along line I-I′ of FIG. 1B.

Referring to FIG. 3B, a semiconductor package 10D may include the substrate 100, the solder ball terminals 500, the semiconductor chip 200, the bumps 300, and the heat dissipation structure 600.

The upper surface 200a of the semiconductor chip 200 may be provided on a higher level than that of the second upper surface 102a of the substrate 100. The level difference C between the upper surface 200a of the semiconductor chip 200 and the first upper surface 101a of the substrate 100 may be about or exactly 50 μm or less, for example, about or exactly 50 μm to about or exactly 0 μm, about or exactly 50 μm to about or exactly 0.1 μm, about or exactly 50 μm to about or exactly 20 μm, or about or exactly 40 μm to about or exactly 10 μm.

The thermally conductive layer 610 may cover the upper surface 200a of the semiconductor chip 200 and the first upper surface 101a of the substrate 100. The thermally conductive layer 610 may buffer the level difference between the upper surface 200a of the semiconductor chip 200 and the first upper surface 101a of the substrate 100. Since the thermally conductive layer 610 has a thickness of about or exactly 50 μm or more (for example, about or exactly 50 μm to 100 μm), the thermally conductive layer may well buffer the level difference C between the upper surface 200a of the semiconductor chip 200 and the first upper surface 101a of the substrate 100. The upper surface of the thermally conductive layer 610 may be flat or substantially flat. That is, the level difference may be filled by the thermally conductive layer 610 to provide the flat or substantially flat upper surface of the thermally conductive layer 610.

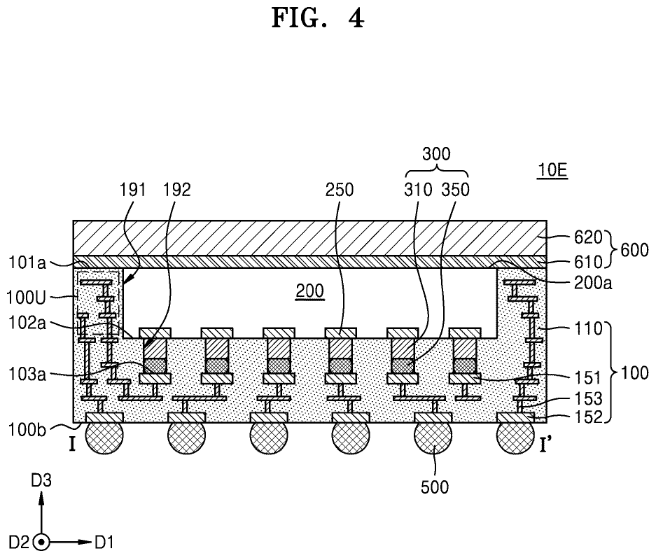

FIG. 4 is a cross-sectional view for explaining the semiconductor package according to some example embodiments, taken along line I-I′ of FIG. 1A and line I-I′ of FIG. 1B.

Referring to FIG. 4, a semiconductor package 10E may include the substrate 100, the solder ball terminals 500, the semiconductor chip 200, the bumps 300, and the heat dissipation structure 600.

The substrate 100 may include an insulating layer 110, first substrate pads 151, second substrate pads 152, and substrate wirings 153. The upper portion 100U of the substrate 100 may include an upper portion of the insulating layer 110. Some of the substrate wirings 153 may be further provided in the upper portion 100U of the substrate 100. For example, some of the substrate wirings 153 may be horizontally apart from the semiconductor chip 200. Since some of the substrate wirings 153 are further provided in the upper portion 100U of the substrate 100, the limitations on the arrangement of the substrate wirings 153 may be reduced.

Some example embodiments of the inventive concepts may be combined with each other. In some example embodiments, at least two of the example embodiments of FIGS. 1A to 1D, the example embodiments of FIG. 1C, the example embodiments of FIG. 1D, the example embodiments of FIG. 1E, the example embodiments of FIG. 1F, the example embodiments of FIG. 1G, the example embodiments of FIG. 2A, the example embodiments of FIG. 2B, the example embodiments of FIG. 3A, the example embodiments of FIG. 3B, and the example embodiments of FIG. 4 may be combined with each other. For example, the semiconductor package 10A of FIG. 2A, the semiconductor package 10B of FIG. 2B, the semiconductor package 10C of FIG. 3A, the semiconductor package 10D of FIG. 3B, and the semiconductor package 10E of FIG. 4 may further include the flux pattern 450 of FIG. 1E. The combination of example embodiments may be varied in various ways.

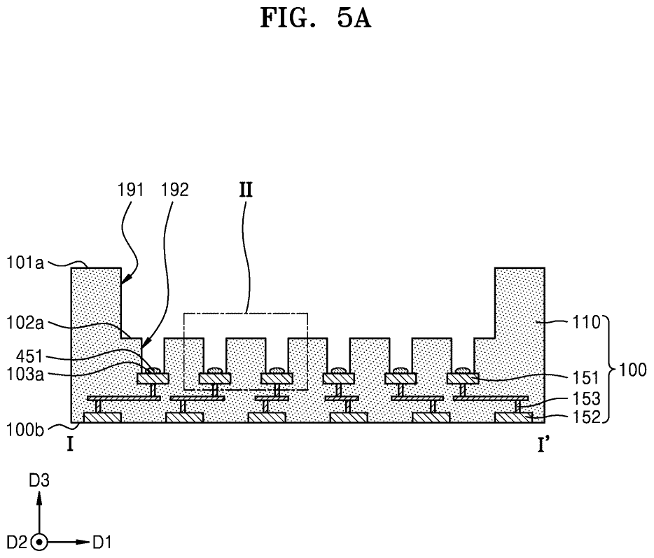

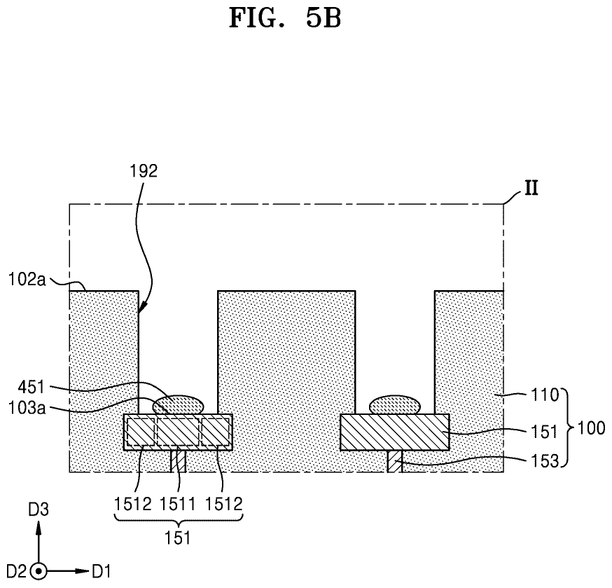

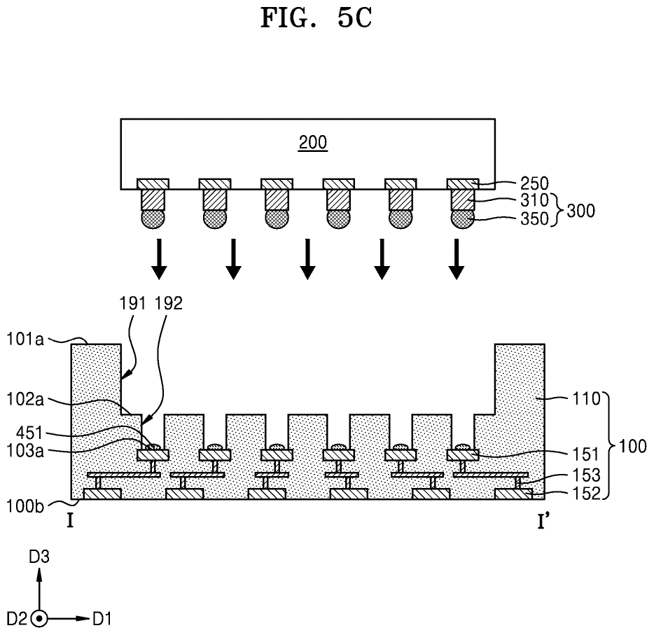

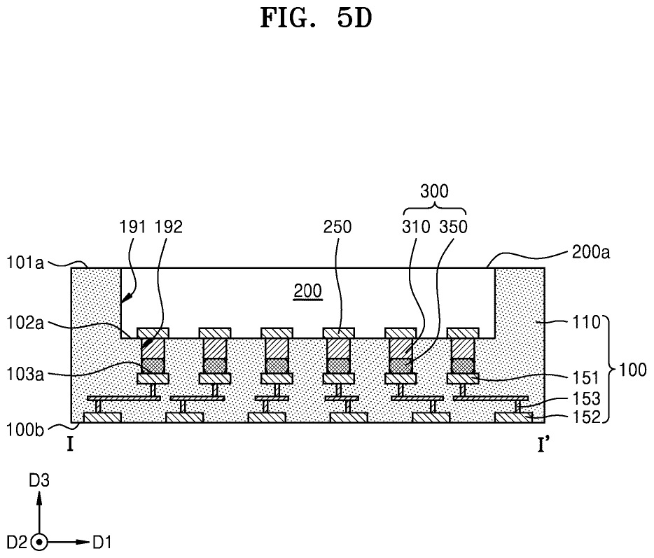

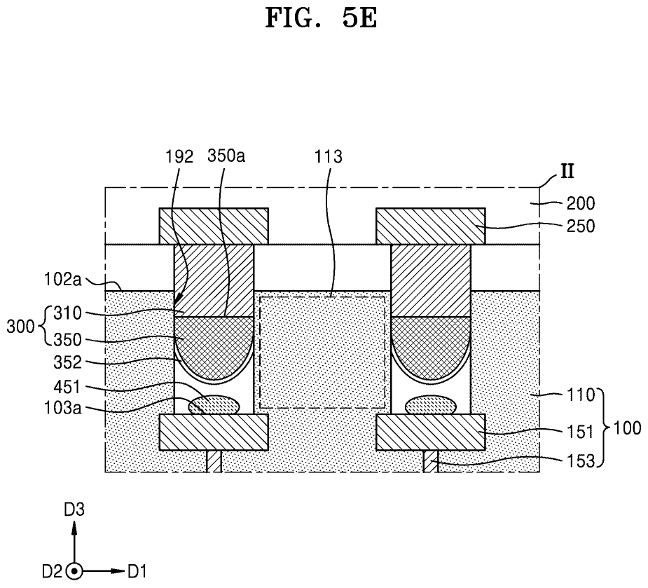

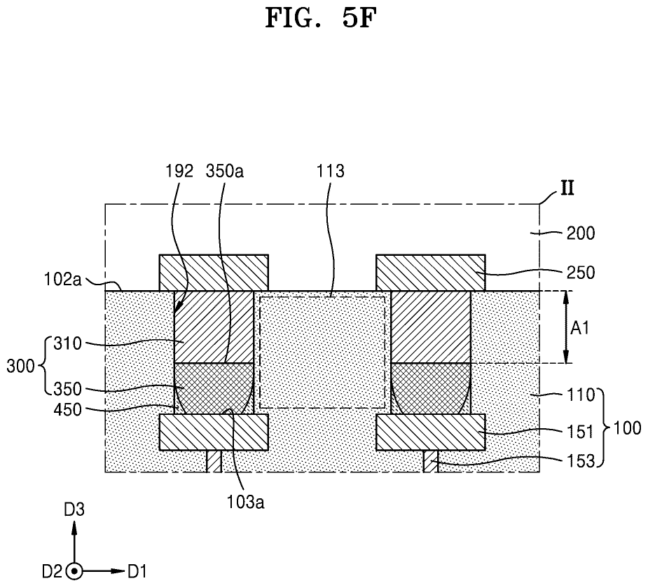

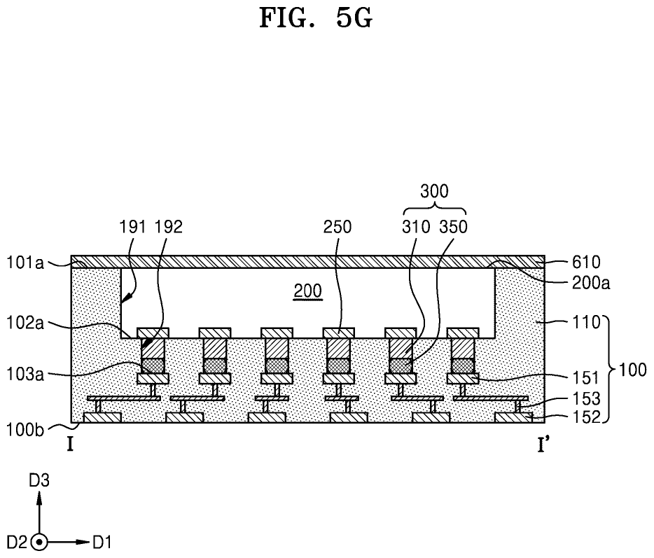

FIGS. 5A to 5G are cross-sectional views for explaining a method of manufacturing the semiconductor package. FIG. 5A is a cross-sectional view of the substrate of FIG. 1B taken along line I-I′. FIG. 5B is an enlarged view of region II of FIG. 5A. FIGS. 5C, 5D, and 5G are cross-sections taken along the line I-I′ of FIG. 1A.

Referring to FIGS. 5A and 5B with FIG. 1B, the substrate 100 may be prepared. The substrate 100 may be the same or substantially the same as the description of the examples of FIGS. 1A to 1D or the example of FIG. 4. For example, the substrate 100 may include the insulating layer 110, the first substrate pads 151, the second substrate pads 152, and the substrate wirings 153.

The substrate 100 may include a first recess portion 191 and second recess portions 192. The second recess portions 192 may expose the first substrate pads 151. The upper portions of the second recess portions 192 may be connected to the first recess portion 191. The upper portion of the first recess portion 191 may be open towards the outside.

Flux layers 451 may be formed on the upper surfaces of the first substrate pads 151, respectively. The flux layers 451 may be respectively formed in the second recess portions 192. The forming of the flux layers 451 may be performed through a coating process using a flux material. The coating process may include a dotting method. For example, each of the first substrate pads 151 may include a first portion 1511 and a second portion 1512. As shown in FIG. 5B, the flux layers 451 may each cover the upper surface of the first portion 1511 of the first substrate pad 151 corresponding to the flux layer 451 and expose the second portion 1512 of the first substrate pad 151 corresponding to the flux layer 451. In some examples, the flux layers 451 may each cover the upper surface of the first portion 1511 and the upper surface of the second portion 1512 of the first substrate pad 151 corresponding to the flux layer 451. In this case, the flux layers 451 may not expose the upper surfaces of the first substrate pads 151.

Referring to FIG. 5C, the semiconductor chip 200 including the bumps 300 may be prepared. The bumps 300 may be provided on the lower surface of the semiconductor chip 200 to be respectively connected to the plurality of chip pads 250.

The semiconductor chip 200 may be provided on the substrate 100 such that the semiconductor chip 200 is vertically aligned with the first recess portion 191. In this case, the position of the semiconductor chip 200 may be adjusted such that the bumps 300 are vertically aligned with the second recess portions 192. Herein, vertically aligned with another component may refer to aligning within a process error range.

The semiconductor chip 200 may be lowered. The semiconductor chip 200 may be provided in the first recess portion 191, and the bumps 300 may be provided in the second recess portions 192. The lower surface of each of the bumps 300 may be the lower surface of the solder ball 350. For example, the solder ball 350 may be vertically aligned with the first substrate pad 151 corresponding to the solder ball 350.

Referring to FIG. 5D, the reflow process of the bumps 300 may be performed to electrically connect the semiconductor chip 200 to the substrate 100. Reflowing the bumps 300 may include heat treatment of the bumps 300. The heat treatment may be performed at a temperature equal to or greater than the melting point of the solder ball 350. The solder ball 350 may be bonded with the first substrate pad 151 corresponding to the solder ball 350. For example, the solder ball 350 may be physically in contact with and electrically connected to the first substrate pad 151. Hereinafter, with reference to FIGS. 5E and 5F, the reflow process of the bumps 300 according to some example embodiments will be described in more detail.

FIG. 5E is a diagram for explaining an arrangement between the substrate, the flux layer, the solder ball, and the semiconductor chip in the lowering process of the semiconductor chip and corresponds to an enlarged view of region II of FIG. 5D. FIG. 5F is a diagram for explaining an arrangement between the substrate, the flux pattern, the solder ball, and the semiconductor chip after the reflow process is completed and corresponds to an enlarged view of region II of FIG. 5D. Hereinafter, for simplification of description of FIGS. 5E and 5F, a single first substrate pad and a single flux layer are described.

Sequentially referring to FIGS. 5E and 5F, an oxide layer 352 may be formed on the solder ball 350 to cover the solder ball 350. For example, the oxide layer 352 may be provided on the lower surface of the solder ball 350. The oxide layer 352 may cover a portion of the side wall of the solder ball 350. The oxide layer 352 may be formed before the reflow process. The oxide layer 352 may be a native oxide layer. If the oxide layer 352 remains in the reflow process, the oxide layer 352 may interfere with the bonding between the solder ball 350 and the first substrate pad 151.

According to the embodiments, the semiconductor chip 200 may be lowered such that the solder ball 350 becomes in contact with the flux layer 451. The flux layer 451 may remove the oxide layer 352. Accordingly, the lower surface of the solder ball 350 may be exposed. If the lowering of the semiconductor chip 200 continues, the solder ball 350 may press the flux pattern 450 to move the flux layer 451 to an edge region of the first substrate pad 151. The solder ball 350 may be physically in contact with the first substrate pad 151. The solder ball 350 may be bonded with the first substrate pad 151 through the reflow process of the solder ball 350. The flux layer 451 may prevent or reduced the solder ball 350 from oxidizing in the reflow process of the solder ball 350. Since the flux layer 451 is provided, the solder ball 350 may be well bonded with the first substrate pad 151. Electrical connection characteristics between the solder ball 350 and the first substrate pad 151 may be improved.

In some example embodiments, the volume of the flux layer 451 may be adjusted such that the flux layer 451 may not interfere with the connection between the solder ball 350 and the first substrate pad 151 in the reflow process. Accordingly, the removal process of the flux layer 451 may be omitted. The manufacturing process of the semiconductor package may be further simplified and improved.

After the reflow process is completed as shown in FIG. 5F, the remaining flux layer 451 may form the flux pattern 450. The flux pattern 450 may be a residue of the flux layer 451. For example, the flux pattern 450 may be provided in the second recess portion 192 and cover at least a portion of the solder ball 350. The flux pattern 450 may be provided, for example, between the solder ball 350 and the substrate 100.

In some examples, in the reflow process of the bumps 300, the solder ball 350 may be melt and mixed with the flux layer 451 and the flux layer 451 may be removed. When the reflow process is completed, the flux layer 451 may not remain as shown in FIG. 1D. Accordingly, the flux pattern 450 of FIG. 5F may not be formed. In this case, the solder ball 350 may further include a flux material.

In some example embodiments, since the partition walls 113 are provided between the plurality of bumps 300, an under-fill layer may not be formed between the bumps 300. Accordingly, the manufacturing process of the semiconductor package may be further simplified and improved.

In some example embodiments, the second upper surface 102a of the semiconductor chip 200 may be provided on a higher level than that of the upper surface 350a of the solder ball 350. Accordingly, in the reflow process of the solder ball 350, the solder ball 350 may be prevented or reduced from flowing into adjacent second recess portions 192. The occurrence of electrical shorts between the bumps 300 may be further prevented or reduced. A space between the lower surface of the semiconductor chip 200 and the second upper surface 102a of the substrate 100 may be 50% or less (for example, 0% or 0.1%) than a height A1 of the conductive pillar 310.

Referring to FIG. 5D again, the upper surface 200a of the semiconductor chip 200 may be provided on the same or a similar level as the first upper surface 101a of the substrate 100. For example, a level difference between an upper surface 200a of the semiconductor chip 200 and the first upper surface 101a of the substrate 100 may be about or exactly 50 μm or less, about or exactly 50 μm to about or exactly 0 μm, for example, about or exactly 50 μm to about or exactly 0.1 μm, about or exactly 50 μm to about or exactly 20 μm, or about or exactly 40 μm to about or exactly 10 μm. An upper portion 100U of the substrate 100 may surround the side walls of the semiconductor chip 200.

Referring to FIG. 5G, the thermally conductive layer 610 may be formed on the semiconductor chip 200 and the substrate 100 to cover the upper surface 200a of the semiconductor chip 200 and the first upper surface 101a of the substrate 100. The thermally conductive layer 610 may buffer the level difference between the upper surface 200a of the semiconductor chip 200 and the first upper surface 101a of the substrate 100.

Referring to FIG. 1C, the heat dissipation plate 620 may be provided on the thermally conductive layer 610 to form the heat dissipation structure 600. The heat dissipation plate 620 may be attached to the semiconductor chip 200 and the substrate 10 the thermally conductive layer 610. In some example embodiments, the upper portion 100U of the substrate 100 may be provided on the side walls of the semiconductor chip 200 and the heat dissipation structure 600 may be provided on the upper surface 200a of the semiconductor chip 200. Accordingly, the forming of the molding layer may be omitted, thereby further simplifying the manufacturing process of the semiconductor package 10. The semiconductor package 10 may be manufactured more efficiently.

The solder ball terminals 500 may be respectively provided on the second substrate pads 152 to be connected to the second substrate pads 152.

According to the examples described above, the manufacturing of the semiconductor package 10 may be completed.

According to the inventive concepts, the substrate may include the first recess portion and the second recess portions. The semiconductor chip may be provided in the first recess portion. The bumps may be provided in the second recess portions. Accordingly, the under-fill layer or the molding layer may not be formed. The manufacturing process of the semiconductor package may be simplified and improved and the semiconductor package may be manufactured more efficiently.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

The detailed descriptions of the inventive concepts are not intended to limit the inventive concepts to the disclosed example embodiment, and may be used in various other combinations, changes and environments within the scope of the inventive concepts.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a substrate defining a first recess portion and a plurality of second recess portions, the plurality of second recess portions on a bottom surface of the first recess portion;
a semiconductor chip in the first recess portion of the substrate;
solder balls in the plurality of second recess portions of the substrate and electrically connected to the semiconductor chip; and
a heat dissipation structure on the substrate and the semiconductor chip,
the bottom surface of the first recess portion of the substrate being on a higher level than upper surfaces of the solder balls.

2. The semiconductor package of claim 1, wherein the bottom surface of the first recess portion of the substrate is in physical contact with the semiconductor chip.

3. The semiconductor package of claim 1, further comprising flux patterns between side walls of the plurality of second recess portions of the substrate and the solder balls.

4. The semiconductor package of claim 1, further comprising conductive pillars between the semiconductor chip and the solder balls.

5. The semiconductor package of claim 4, wherein a space between the bottom surface of the first recess portion of the substrate and a lower surface of the semiconductor chip is 50% to 0% of a height of the conductive pillars.

6. The semiconductor package of claim 5, wherein a first gap region is between the bottom surface of the first recess portion of the substrate and the semiconductor chip, and the first gap region defines an empty space being in a vacuum state or occupied by a gas.

7. The semiconductor package of claim 4, wherein second gap regions are provided between side walls of the plurality of second recess portions of the substrate and the conductive pillars, and the second gap regions define empty spaces being in vacuum states or occupied by a gas.

8. The semiconductor package of claim 1, wherein the solder balls include a first solder ball, and a side wall of the first solder ball is in physical contact with the substrate.

9. The semiconductor package of claim 1, wherein a side wall of the semiconductor chip is in physical contact with the substrate.

10. The semiconductor package of claim 1, wherein the heat dissipation structure comprises:
a thermally conductive layer covering a first upper surface of the substrate and an upper surface of the semiconductor chip; and
a heat dissipation plate on the thermally conductive layer.

11. The semiconductor package of claim 10, wherein a level difference between the first upper surface of the substrate and the upper surface of the semiconductor chip is 50 μm to 0 μm.

12. A semiconductor package comprising:
a substrate comprising a first upper surface, a second upper surface on a lower level than the first upper surface, and a third upper surface on a lower level than the second upper surface;
bumps on the third upper surface of the substrate; and
a semiconductor chip on the second upper surface of the substrate and on the bumps and connected to the bumps,
each of the bumps comprising a conductive pillar and a solder ball on a lower surface of the conductive pillar,
at least a portion of the second upper surface of the substrate being between the bumps and on a higher level than the upper surface of the solder ball.

13. The semiconductor package of claim 12, wherein the second upper surface of the substrate is in physical contact with a lower surface of the semiconductor chip.

14. The semiconductor package of claim 12, wherein an upper portion of the substrate is on side walls of the semiconductor chip and surrounds the side walls of the semiconductor chip, in a planar view.

15. The semiconductor package of claim 12, wherein
the substrate comprises a partition wall,
the partition wall is between the bumps, and
the second upper surface of the substrate comprises an upper surface of the partition wall.

16. The semiconductor package of claim 12, further comprising:
a metal layer on an upper surface of the semiconductor chip and on the first upper surface of the substrate; and
a thermally conductive layer between the semiconductor chip and the metal layer and between the substrate and the metal layer.

17. A semiconductor package comprising:
a substrate defining a first recess portion and a plurality of second recess portions, the first recess portion is defined by a first upper surface of the substrate and the plurality of second recess portions are defined by and extend from a bottom surface of the first recess portion;
solder ball terminals on a lower surface of the substrate;
a semiconductor chip in the first recess portion of the substrate;
bumps in the plurality of second recess portions of the substrate and connected to the semiconductor chip;
a heat dissipation plate on the substrate and on the semiconductor chip; and
a thermally conductive layer between the semiconductor chip and the heat dissipation plate and between the substrate and the heat dissipation plate so as to cover an upper surface of the semiconductor chip,
the bottom surface of the first recess portion of the substrate being on a lower level than the first upper surface of the substrate, and
bottom surfaces of the plurality of second recess portions of the substrate being on a lower level than the bottom surface of the first recess portion of the substrate,
the substrate comprising:
first substrate pads exposed through the plurality of second recess portions and connected to the bumps;
substrate wirings in the substrate and connected to the first substrate pads; and
second substrate pads on the lower surface of the substrate and between the substrate wirings and the solder ball terminals,
each of the bumps comprising a conductive pillar and a solder ball on a lower surface of the conductive pillar, and
the bottom surface of the first recess portion of the substrate being on a higher level than the lower surface of the conductive pillar.

18. The semiconductor package of claim 17, wherein side walls of the bumps are in physical contact with side walls of the plurality of second recess portions of the substrate.

19. The semiconductor package of claim 17, further comprising a flux pattern provided in at least one of the plurality of second recess portions of the substrate and covering side walls of the solder ball.

20. The semiconductor package of claim 17, wherein
an upper portion of the substrate is between a side wall of the semiconductor chip and a side wall of the substrate, and
portions of the substrate wirings are in the upper portion of the substrate.
